(19) United States
(12) Patent Application Publication
(10) Pub. No.: US 2025/0096090 A1
(43) Pub. Date: Mar. 20, 2025

(54) INTEGRATED DEVICE COMPRISING SILICON SUBSTRATE WITH POROUS PORTION

(71) Applicant: QUALCOMM Incorporated, San Diego, CA (US)

(72) Inventors: Ranadeep DUTTA, Del Mar, CA (US); Jonghae KIM, San Diego, CA (US); Je-Hsiung LAN, San Diego, CA (US)

(21) Appl. No.: 18/468,493

(22) Filed: Sep. 15, 2023

(51) Int. Cl. H01L 23/498; H01L 23/00; H01L 23/31; H01L 25/065

(52) U.S. Cl. CPC H01L 23/49822; H01L 23/3171; H01L 23/49838; H01L 24/08; H01L 24/16; H01L 25/0652; H01L 2224/08146; H01L 2224/08165; H01L 2224/16227; H01L 2224/16235; H01L 2924/1431; H01L 2924/182; H01L 2924/3511

(57) ABSTRACT

An integrated device comprising a die substrate comprising a porous portion; a plurality of through substrate vias extending through the porous portion of the die substrate; and a die interconnection portion coupled to the die substrate.

### FIELD

Various features relate to integrated devices.

### BACKGROUND

A package may include a substrate and integrated devices. These components are coupled together to provide a package that may perform various electrical functions. The performance of a package and its components may depend on the number and/or density of interconnects that may be provided in a package and/or an integrated device. There is an ongoing need to provide packages with higher density interconnects and/or more interconnects in a given region.

### SUMMARY

Various features relate to integrated devices.

One example provides an integrated device comprising a die substrate comprising a porous portion; a plurality of through substrate vias extending through the porous portion of the die substrate; and a die interconnection portion coupled to the die substrate.

Another example provides a package comprising an interposer and a first integrated device coupled to the interposer through at least a plurality of solder interconnects. The first integrated device comprises a die substrate comprising a porous portion; a plurality of through substrate vias extending through the porous portion of the die substrate; and a die interconnection portion coupled to the die substrate.

Another example provides a package comprising a substrate and a first integrated device coupled to the substrate through at least a plurality of solder interconnects. The first integrated device comprises a die substrate comprising a porous portion; a plurality of through substrate vias extending through the porous portion of the die substrate; and a die interconnection portion coupled to the die substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary integrated device that includes a die substrate with a porous portion.

FIG. 2 illustrates a cross sectional profile view of an exemplary integrated device that includes a die substrate with a porous portion and a cavity.

FIG. 3 illustrates a cross sectional profile view of an exemplary package that includes a substrate and an integrated device that includes a die substrate with a porous portion.

FIG. 4 illustrates a close-up view of an exemplary package that includes a substrate and an integrated device that includes a die substrate with a porous portion.

FIGS. 5A-5F illustrate an exemplary sequence for fabricating an integrated device that includes a die substrate with a porous portion and a cavity.

FIG. 6 illustrates an exemplary flow diagram of a method for fabricating an integrated device that includes a die substrate with a porous portion and a cavity.

FIG. 7 illustrates a cross sectional profile view of an exemplary package that includes a substrate, an interposer and an integrated device that includes a die substrate with a porous portion.

FIG. 8 illustrates an exemplary sequence for fabricating an interposer.

FIGS. 9A-9B illustrate an exemplary sequence for fabricating a package that includes a substrate, an interposer and an integrated device that includes a die substrate with a porous portion.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes an integrated device comprising a die substrate comprising a porous portion; a plurality of through substrate vias extending through the porous portion of the die substrate; and a die interconnection portion coupled to the die substrate. The integrated device may be coupled to a substrate or an interposer. In some implementations, the die substrate includes silicon. The die substrate may include an unporosified portion, and the porous portion of the die substrate may include a lower density than the unporosified portion of the die substrate. In some implementations, the porous portion comprises a first porous portion comprising a first density; and a second porous portion comprising a second density. In some implementations, the first porous portion comprises a first coefficient of thermal expansion (CTE), and the second porous portion comprises a second coefficient of thermal expansion (CTE) that is different from the first coefficient of thermal expansion (CTE). The use of one or more porous portions in the die substrate allows for more through substrate vias in the die substrate than would otherwise be possible, due to the reduction in the CTE mismatch between the CTE of the plurality of through substrate vias and the CTE of the die substrate. More through substrate vias means higher density interconnects through the back side of the integrated device, which can lead to improved performance in the integrated device.

### Exemplary Integrated Device Comprising a Die Substrate with a Porous Portion

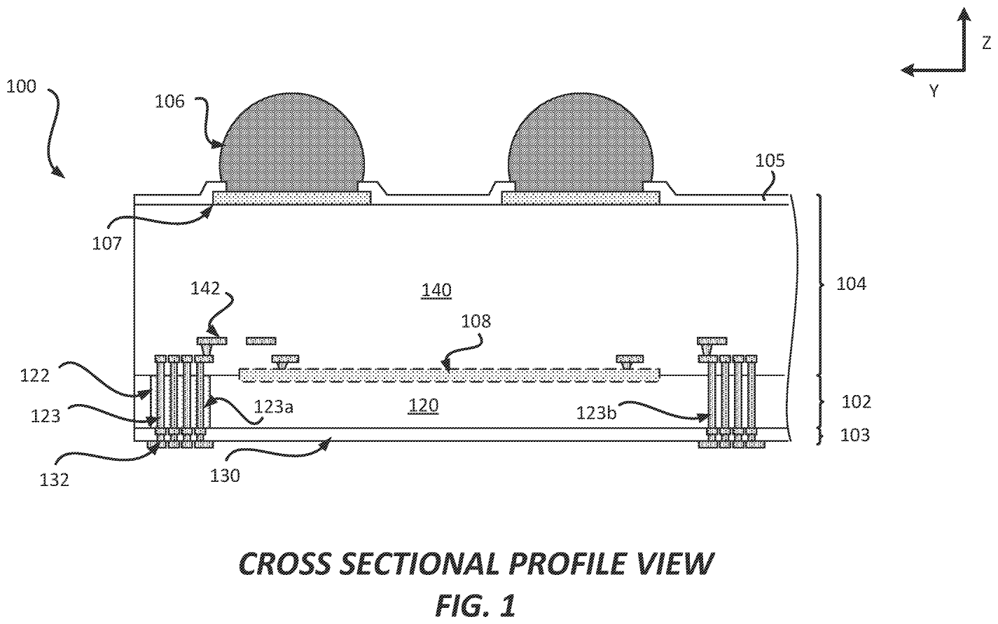

FIG. 1 illustrates a cross sectional profile view of an integrated device 100 that includes a die substrate with a porous portion. The integrated device 100 includes a die substrate portion 102, a metallization portion 103, and a die interconnection portion 104. The die substrate portion 102 includes a die substrate 120, an active region 108 and a plurality of through substrate vias 123. The active region 108 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 108 of the die substrate 120.

The die substrate 120 may include silicon (Si). The die substrate 120 may include a porous portion 122. The die substrate 120 may comprise a bulk silicon that includes a porous portion 122. The porous portion 122 may be a portion of the die substrate 120 that has a different porosity, different density and/or different coefficient of thermal expansions (CTEs) from that of a bulk silicon. The porous portion 122 may be a local portion and/or localized portion of the die substrate 120. A porosification process may be used to form the porous portion 122. A porous portion of material as used in the disclosure is a portion of the material that has been porosified using a porosification process. As will be further described below, the porous portion 122 allows more through substrate vias to be formed in the die substrate 120, with minimal warpage issues due to mismatch in the coefficient of thermal expansions (CTEs) of the die substrate 120 and the plurality of through substrate vias 123. The plurality of through substrate vias 123 extend through the porous portion 122 of the die substrate 120. However, in some implementations, a plurality of through substrate vias 123 may also extend through an unporosified portion of the die substrate 120. The plurality of through substrate vias 123 includes a first plurality of through substrate vias 123a and a second plurality of through substrate vias 123b. The first plurality of through substrate vias 123a extend through the porous portion 122 of the die substrate 120. The second plurality of through substrate vias 123b extend through an unporosified portion of the die substrate 120 (e.g., bulk portion of the die substrate 120). The term unporosified portion means that a portion of the die substrate 120 has not undergone a porosification process that increases the porosity of the die substrate.

It is noted that the porous portion 122 may include several porous portions. Thus, a die substrate 120 may include a first porous portion, a second porous portion, a third porous portion and so on and so forth. Therefore, a die substrate 120 may include a plurality of porous portions. Each porous portion may include a plurality of through substrate vias that extend through that respective porous portion. The size of each porous portion may be different with different implementations.

When the die substrate portion 102 includes silicon, the unporosified portion of the die substrate 120 may have a coefficient of thermal expansion (CTE) of about 2.6 parts per million per Celsius degree (ppm/C). When the plurality of through substrate vias 123 include copper (Cu), the plurality of through substrate vias 123 may have a coefficient of thermal expansion (CTE) of about 17 parts per million per Celsius degree (ppm/C). The mismatch in the CTE of the die substrate 120 and the CTE of the plurality of through substrate vias 123 means that the area of the plurality of through substrate vias 123 cannot be greater than 1 percent of the area of the die substrate 120. Anything greater than 1 percent can lead to warpage issues in the integrated device 100. To address the warpage issue and increase the ability of the die substrate 120 to have more plurality of through substrate vias 123, the die substrate 120 may be processes to include one or more porous portions and/or portions of the die substrate 120 to be more porous. Increasing the porosity of the entire die substrate (e.g., 120) or portions of the die substrate 120, results in the porous portion to be less dense, relative to other parts of the die substrate 120 or the bulk die substrate. Increasing the porosity of a portion of the die substrate 120 may also increase the CTE of the porous portion of the die substrate 120, resulting in less mismatch between the CTE of the porous portion of the die substrate 120 and the CTE of the plurality of through substrate vias 123. A decrease in the mismatch of the CTE of the porous portion to the CTE of the plurality of through substrate vias 123 means that more through substrate vias 123 may be formed and extended in the die substrate 120. The number of through substrate vias 123 that may be formed in the porous portion of the die substrate 120 may depend on the porosity of the porous portion. A higher porosity may mean more through substrate vias may be formed in the porous portion relative to another porous portion with a lower porosity. In some implementations, one or more porous portions may have a porosity in a range of 30%-70%. Different porous portions may have different porosity.

In some implementations, a porosity of a material may be a measure of the void (e.g., empty spaces) in the material, and is a fraction of the volume of voids over the total volume, as a percentage between 0% and 100%. A porosity of a material may be quantified by the weight of the material measured before and after porosification. A higher level of porosity leads to a lower mass density. As an example, the density of a bulk silicon (Si) may be about 2.33 grams per cubic centimeter (g/cc). A silicon that has 30% porosity, may have a density of about 1.63 grams per cubic centimeter (g/cc). A silicon that has 20% porosity, may have a density of about 1.86 grams per cubic centimeter (g/cc). A silicon that has X %, may have a density of about 2.33*(100−X)/100. In some implementations, a bulk silicon or a portion of a bulk silicon that has not been porosified, may be referred to as an unporosified silicon and/or an unporosified portion of silicon. Moreover, an unporosified silicon may be referred to as a bulk silicon. An unporosified silicon may have a density of about 2.33 grams per cubic centimeter (g/cc). In some implementations, a bulk silicon may be considered to have 0% porosity.

A porosification process may be used to form and/or define porous portions in the die substrate 120. In some implementations, a porosification process may include dipping a silicon wafer in an electrolyte of 1:1 mixture of hydrofluoric acid (HF) and ethanol. A current is then passed, using a platinum rod as cathode while the silicon wafer acts as anode. The substrate is then annealed at 300-400° C. to strengthen the microstructure. An HF-resistant etch-stop layer (e.g., silicon nitride) is used for selective (masked) porosification. However, different implementations may use a porosification process that includes different steps, other steps and/or other materials.

In some implementations, more than 1% (e.g., 1%-5%, at least 2%) of the surface area of the die substrate 120 may be occupied by a plurality of through substrate vias 123. In some implementations, a first porous portion of the die substrate 120 may have a first porosity, a second porous portion of the die substrate 120 may have a second porosity, and a third porous portion of the die substrate 120 may have a third porosity, where the first porosity, the second porosity and/or the third porosity are different. In some implementations, the first porous portion may have a first CTE, the second porous portion may have a second CTE and the third porous portion may have a third CTE, where the first CTE, the second CTE and the third CTE are different. In some implementations, the first CTE, the second CTE and the third CTE may be different from the CTE of the bulk (unporosified) die substrate 120.

The metallization portion 103 includes at least one dielectric layer 130 and a plurality of metallization interconnects 132. The metallization portion 103 is coupled to the die substrate portion 102. The at least one dielectric layer 130 is coupled to the die substrate 120. The plurality of metallization interconnects 132 may be coupled to the plurality of through substrate vias 123. The plurality of metallization interconnects 132 may include a plurality of redistribution interconnects.

The die interconnection portion 104 includes at least one dielectric layer 140 and a plurality of die interconnects 142. The die interconnection portion 104 is coupled to the die substrate portion 102. The die substrate portion 102 is located between the metallization portion 103 and the die interconnection portion 104. The plurality of die interconnects 142 is coupled to the active region 108 of the die substrate portion 102. The die interconnection portion 104 may also include a plurality of pad interconnects 107 and a passivation layer 105. A plurality of solder interconnects 106 are coupled to the plurality of pad interconnects 107. In some implementations, a back end of line (BEOL) process may be used to fabricate the die interconnection portion 104.

In some implementations, an electrical path to and/or from an active region 108 may include at least one die interconnect from the plurality of die interconnects 142, at least one through substrate via from the plurality of through substrate vias 123 and at least one metallization interconnect from the plurality of metallization interconnects 132.

In some implementations, an electrical path to and/or from an active region 108 may include at least one die interconnect from the plurality of die interconnects 142, at least one pad interconnect from the plurality of pad interconnects 107 and at least one solder interconnect from the plurality of solder interconnects 106.

In some implementations, an electrical path between a solder interconnect from the plurality of solder interconnects 106 and a metallization interconnect from the plurality of metallization interconnects 132 may include at least one through substrate via from the plurality of through substrate vias 123 and at least one die interconnect from the plurality of die interconnects 142.

In some implementations, to further reduce the CTE mismatch between the CTE of the die substrate 120 and the CTE of the plurality of through substrate vias, cavities in the die substrate 120 may be used in conjunction with the porous portion 122.

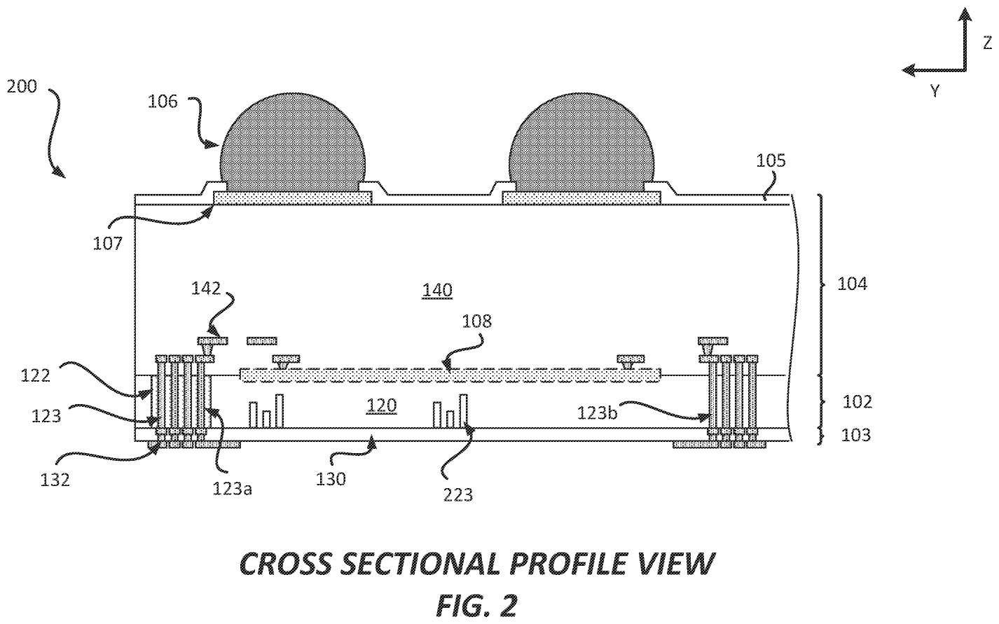

FIG. 2 illustrates a cross sectional profile view of an integrated device 200 that includes a die substrate with a porous portion and a cavity. The integrated device 200 is similar to the integrated device 100, and includes similar components as the integrated device 100. The integrated device 200 includes the die substrate portion 102, the metallization portion 103, and the die interconnection portion 104. The die substrate portion 102 includes the die substrate 120, the active region 108, a porous portion 122, a plurality of through substrate vias 123, and a plurality of cavities 223. The plurality of cavities 223 are located in the die substrate 120. The plurality of cavities 223 may be located in the porous portion 122. The plurality of cavities 223 may have different depths and/or may have the same depth. Providing the plurality of cavities 223 in the die substrate 120 may effectively reduce the overall density of the die substrate 120 and increase the effective CTE of the die substrate 120. This in turn, helps reduce the CTE mismatch between the die substrate 120 and the plurality of through substrate vias 123. As such, more plurality of through substrate vias 123 may be formed and/or provided in the die substrate 120, enabling a higher of interconnects in the integrated device 200. It is noted that forming the plurality of cavities 223 in the die substrate 120 is different from forming a porous portion in the die substrate 120.

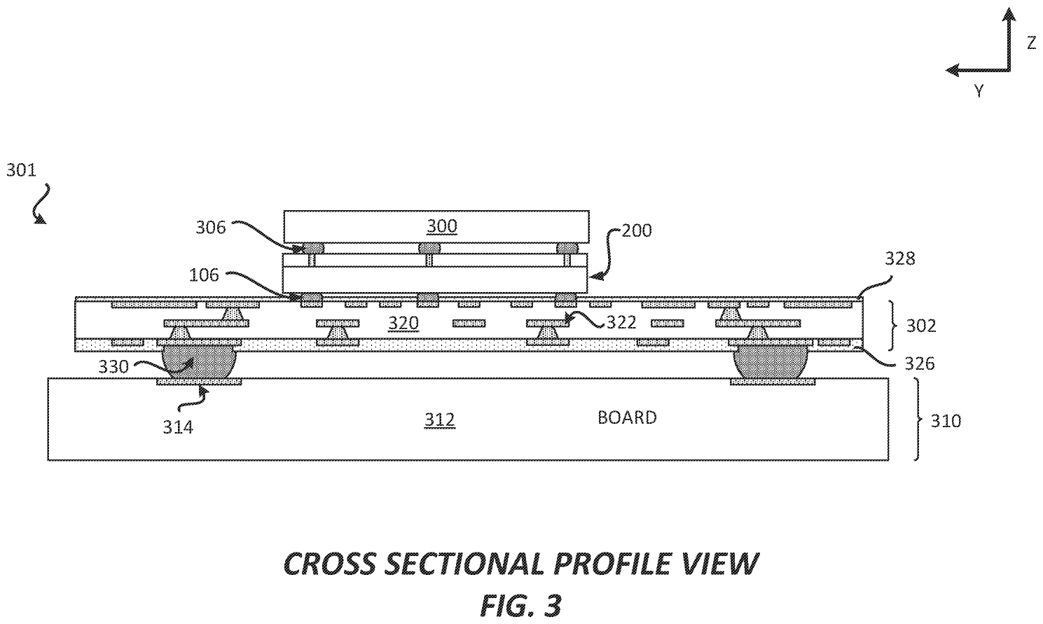

FIG. 3 illustrates a package 301 that includes a substrate 302 and the integrated device 200. The integrated device 200 is coupled to the substrate 302 through a plurality of solder interconnects 106. The package 301 is coupled to a board 310 through a plurality of solder interconnects 330. The board 310 may include a printed circuit board (PCB). The board 310 includes at least one board dielectric layer 312 and a plurality of board interconnects 314. The substrate 302 may include a package substrate. The substrate 302 includes at least one substrate dielectric layer 320, a plurality of substrate interconnects 322, a solder resist layer 326 and a solder resist layer 328. The plurality of solder interconnects 106 are coupled to the plurality of substrate interconnects 322 and the integrated device 200.

An integrated device 300 is coupled to the integrated device 200 through a plurality of solder interconnects 306. The integrated device 300 may be similar to the integrated device 200. The integrated device 300 may or may not have a die substrate with one or more porous portions. The integrated device 300 may or may not have a die substrate with cavities. The integrated device 300 may or may not have a back side metallization portion.

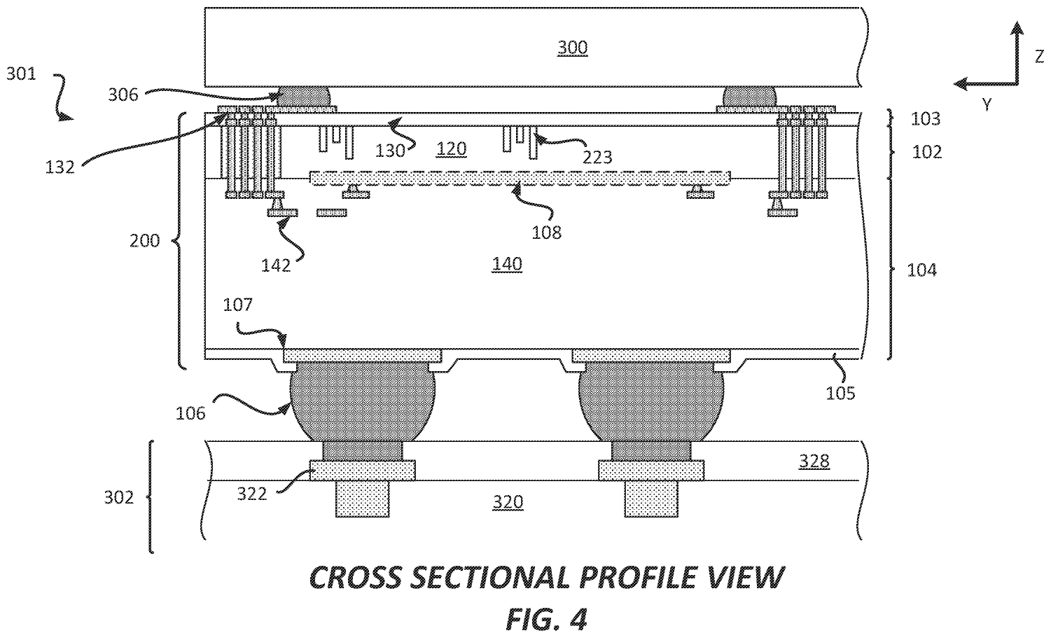

FIG. 4 illustrates a close up of the package 301 of FIG. 3. As shown in FIG. 4, a front side of the integrated device 300 is coupled to the back side of the integrated device 200 through the plurality of solder interconnects 306. The plurality of solder interconnects 306 may be coupled to pad interconnects of the integrated device 300 and metallization interconnects 132 from the metallization portion 103 of the integrated device 200. An electrical path between the integrated device 300 and the integrated device 200 may include a pad interconnect from the plurality of pad interconnects of the integrated device 300, a solder interconnect from the plurality of solder interconnects 306, a metallization interconnect from the plurality of metallization interconnects 132 of the integrated device 200.

An integrated device (e.g., 100) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

### Exemplary Sequence for Fabricating an Integrated Device Comprising a Die Substrate With a Porous Portion

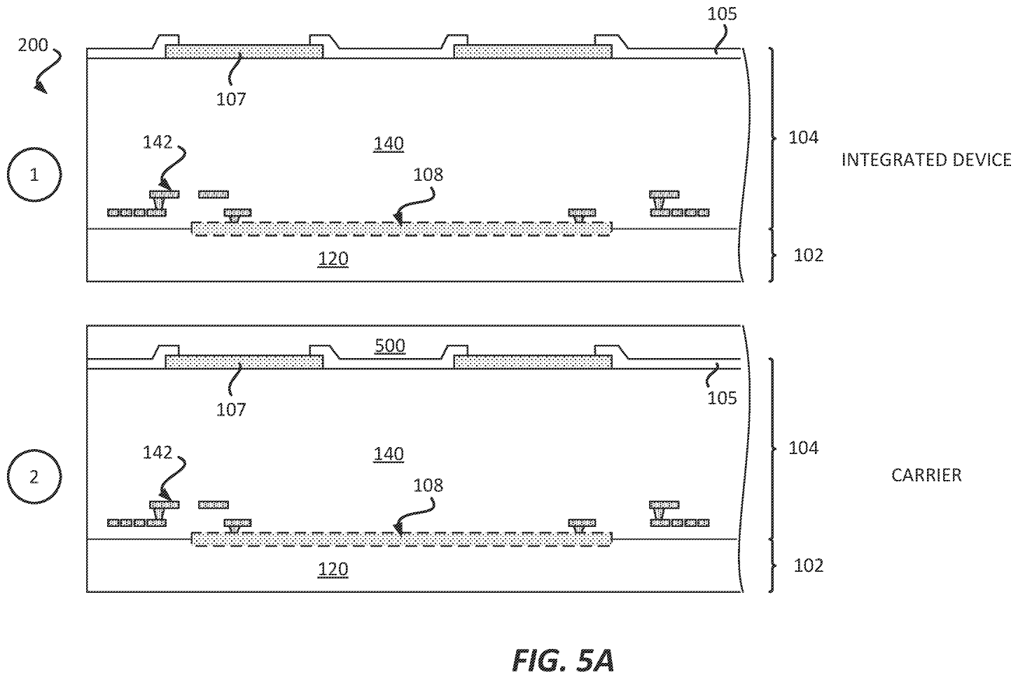

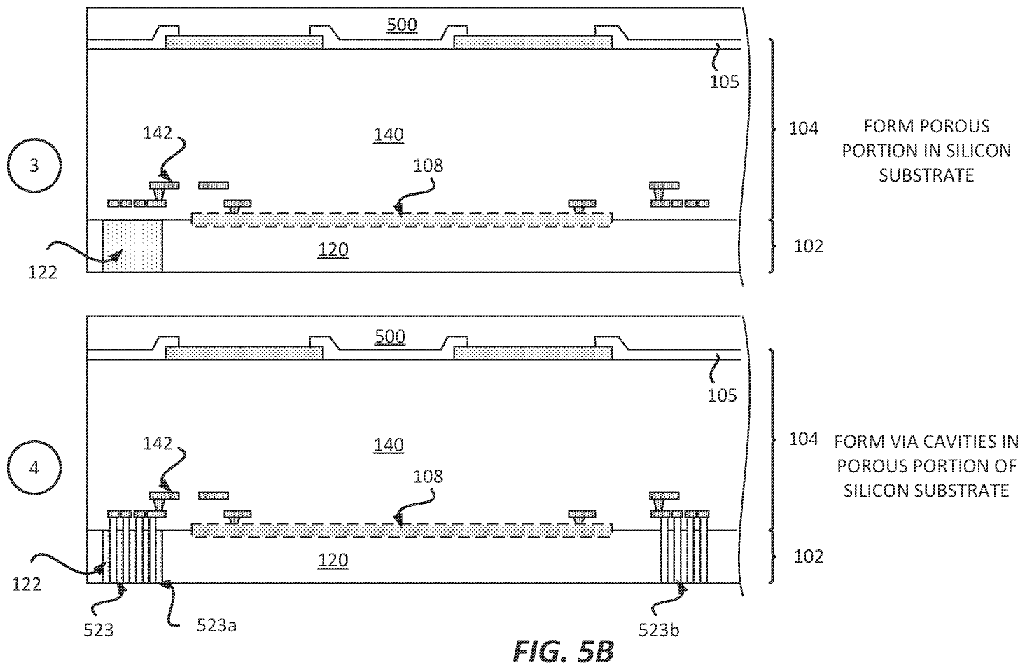

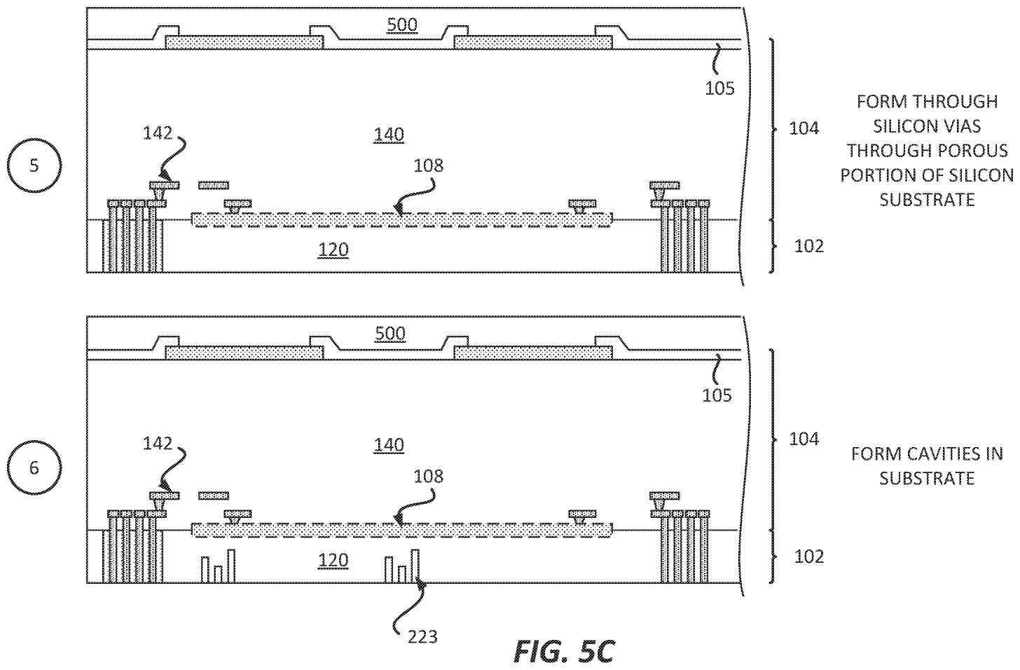

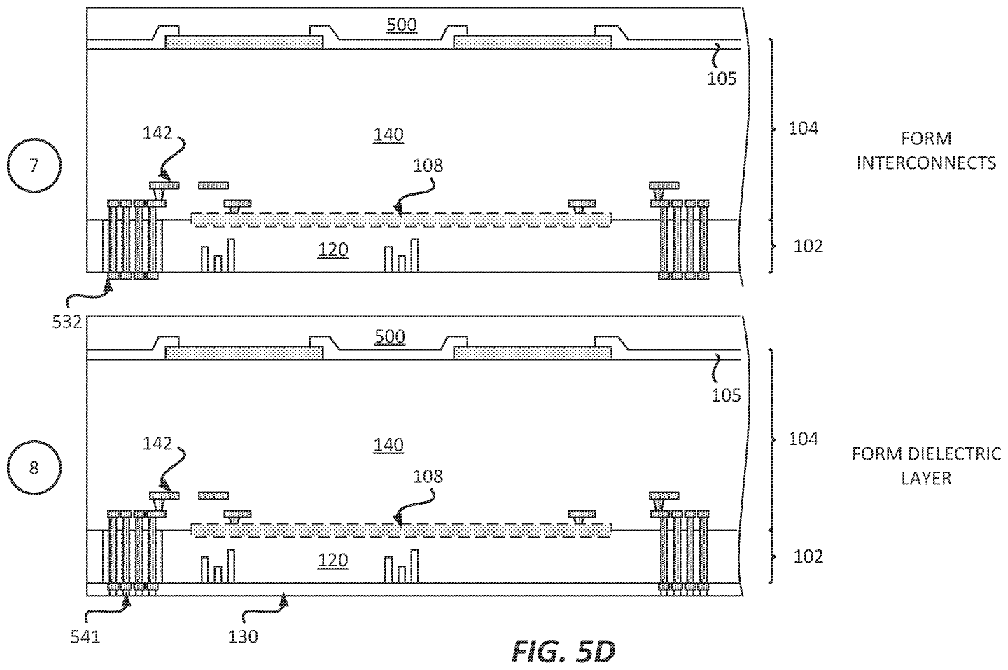

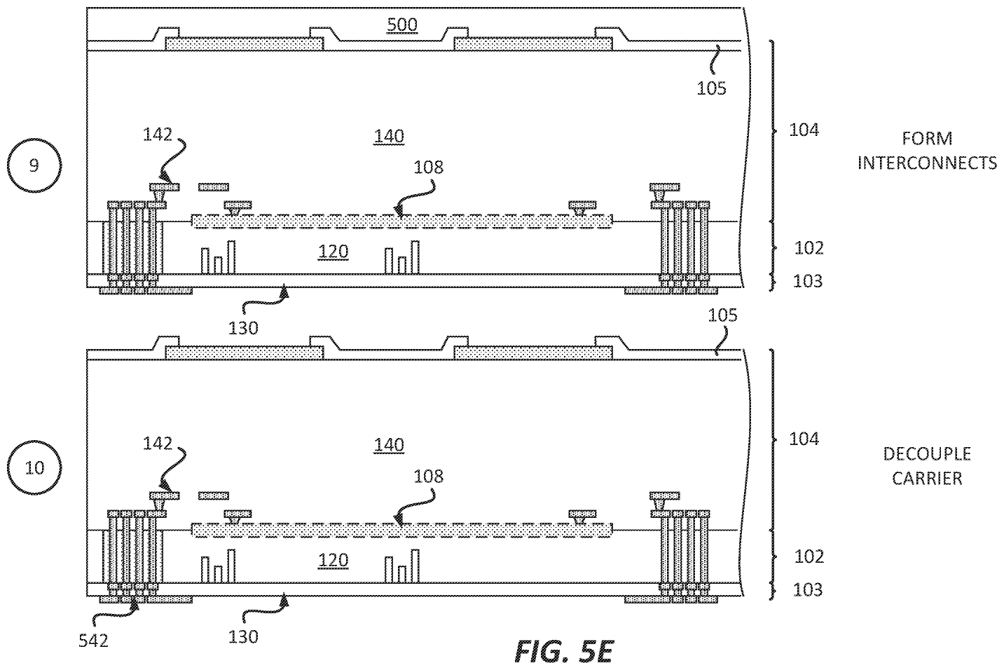

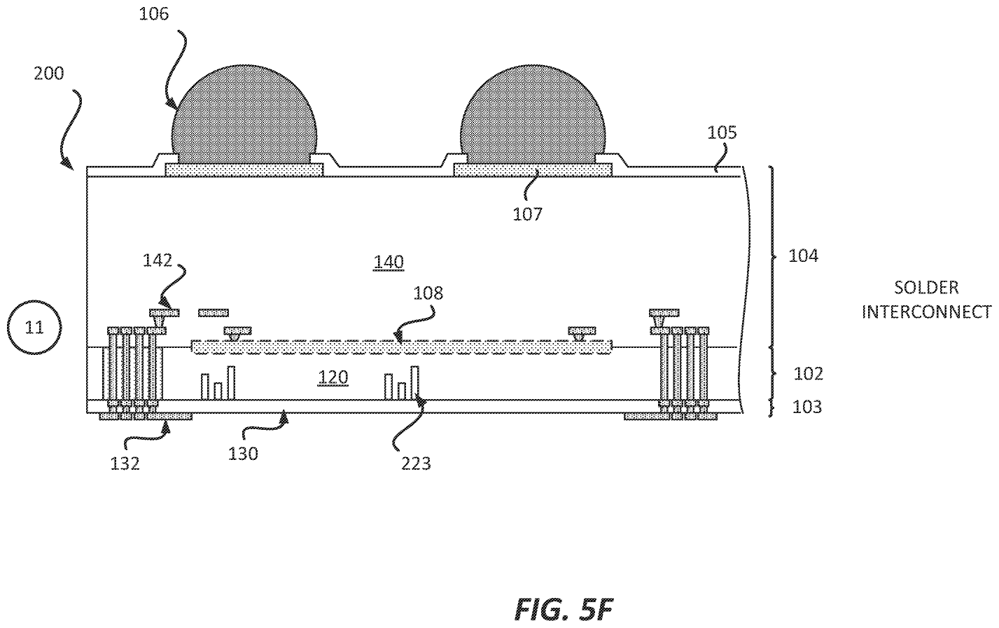

In some implementations, fabricating an integrated device includes several processes. FIGS. 5A-5F illustrate an exemplary sequence for providing or fabricating an integrated device comprising a die substrate with a porous portion and a cavity. In some implementations, the sequence of FIGS. 5A-5F may be used to provide or fabricate the integrated device 200. However, the process of FIGS. 5A-5F may be used to fabricate any of the integrated devices described in the disclosure.

It should be noted that the sequence of FIGS. 5A-5F may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 5A, illustrates a state after an integrated device is provided and/or fabricated. The integrated device 200 may include a die substrate portion 102 and a die interconnection portion 104. The die substrate portion 102 includes a die substrate 120 and an active region 108. The die interconnection portion 104 includes at least one dielectric layer 140, a plurality of die interconnects 142, a plurality of pad interconnects 107 and a passivation layer 105. In some implementations, a front side of the integrated device 200 may include the side that includes the passivation layer 105 and/or the plurality of pad interconnects 107. In some implementations, a back side of the integrated device 200 may include the side that includes the die substrate 120. In some implementations, a front side of the integrated device 200 may include the side that includes the plurality of pad interconnects 107.

Stage 2 illustrates a state after the integrated device 200 is coupled to a carrier 500. The carrier 500 may be a tape. The carrier may include an adhesive. The front side of the integrated device 200 may be coupled to and touching the carrier 500. For example the passivation layer 105 and/or the plurality of pad interconnects 107 may be coupled to and touch the carrier 500.

Stage 3, as shown in FIG. 5B, illustrates a state after at least one porous portion 122 is formed in the die substrate 120. The porous portion 122 may have a lower density than other portions of the die substrate 120. The die substrate 120 may include silicon. In some implementations, more than one porous portion may be formed in the die substrate 120. In some implementations, the porous portion may have different thicknesses.

A porosification process may be used to form and/or define porous portions in the die substrate 120. A porosification process may include dipping a silicon wafer in an electrolyte of 1:1 mixture of HF and ethanol. A current is then passed, using a platinum rod as cathode while the silicon wafer acts as anode. The substrate is then annealed at 300-400° C. to strengthen the microstructure. An HF-resistant etch-stop layer (e.g., silicon nitride) is used for selective (masked) porosification. However, different implementations may use a porosification process that includes other steps and/or materials.

Different porous portions may have the same porosity or different porosity. As a result of the porosification process, the porous portion may have different coefficients of thermal expansions (e.g., different from other porous portions, different from unporosified portions of the die substrate 120). The porosification process may change the density of the porous portion. In some implementations, one or more porous portions (e.g., 122) may have a porosity in a range of about 30%-70%.

Stage 4 illustrates a state after a plurality of via cavities 523 are formed in the die substrate 120. The plurality of via cavities 523 may include a first plurality of via cavities 523a and a second plurality of via cavities 523b. The first plurality of via cavities 523a may be formed through the porous portion 122 of the die substrate 120. The second plurality of via cavities 523b may be formed through the bulk portion of the die substrate 120 (e.g., unporosified portion of the die substrate 120). A laser process (e.g., laser ablation) may be used to form the plurality of via cavities 523. In some implementations, the plurality of via cavities 523 may extend into the die interconnection portion 104.

Stage 5, as shown in FIG. 5C, illustrates a state after a plurality of through substrate vias 123 are formed. A plating process may be used to form the plurality of substrate vias 123. The plurality of through substrate vias 123 may include a first plurality of through substrate vias 123a and a second plurality of through substrate vias 123b. The first plurality of through substrate vias 123a may be formed in the first plurality of via cavities 523a. The first plurality of through substrate vias 123a may extend through the porous portion 122 of the die substrate 120. The second plurality of through substrate vias 123b may be formed in the second plurality of via cavities 523b. The second plurality of through substrate vias 123b may extend through an unporosified portion of the die substrate 120. In some implementations, the plurality of through substrate vias 123 may extend into the die interconnection portion 104. The plurality of through substrate vias 123 may be coupled to the plurality of die interconnects 142.

Stage 6, illustrates a state after a plurality of cavities 223 are formed in the die substrate 120. A laser process (e.g., laser ablation) may be used to form the plurality of cavities 223. The plurality of cavities 223 may have the same depth or different depths. The plurality of cavities 223 may extend through the porous portion 122 and/or the unporosified portion of the die substrate 120.

Stage 7, as shown in FIG. 5D, illustrates a state after a plurality of metallization interconnects 532 are formed on the back side surface of the die substrate 120. A plating process may be used to form the plurality of metallization interconnects 532. The plurality of metallization interconnects 532 may be coupled to the plurality of through substrate vias 123.

Stage 8, illustrates a state after a dielectric layer 130 is formed and coupled to the back side surface of the die substrate 120. The dielectric layer 130 may include a plurality of cavities 541. The dielectric layer 130 and the plurality of cavities 541 may be formed and/or provided using a deposition process, a lamination process, an exposure process and/or a development process.

Stage 9, as shown in FIG. 5E, illustrates a state after a plurality of metallization interconnects 542 are formed. The plurality of metallization interconnects 542 may be coupled to the plurality of metallization interconnects 532. A plating process may be used to form the plurality of metallization interconnects 534. The plurality of metallization interconnects 532 and/or the plurality of metallization interconnects 542 may be represented as the plurality of metallization interconnects 132.

Stage 10 illustrates a state after the carrier 500 is decoupled from the integrated device 200. The carrier 500 may be detached and/or peeled off from the integrated device 200.

Stage 11, as shown in FIG. 5F, illustrates a state after the plurality of solder interconnects 106 are coupled to the plurality of pad interconnects 107. A solder reflow process may be used to form and couple the plurality of solder interconnects 106 to the plurality of pad interconnects 107.

### Exemplary Flow Diagram of a Method for Fabricating an Integrated Device Comprising a Die Substrate With a Porous Portion

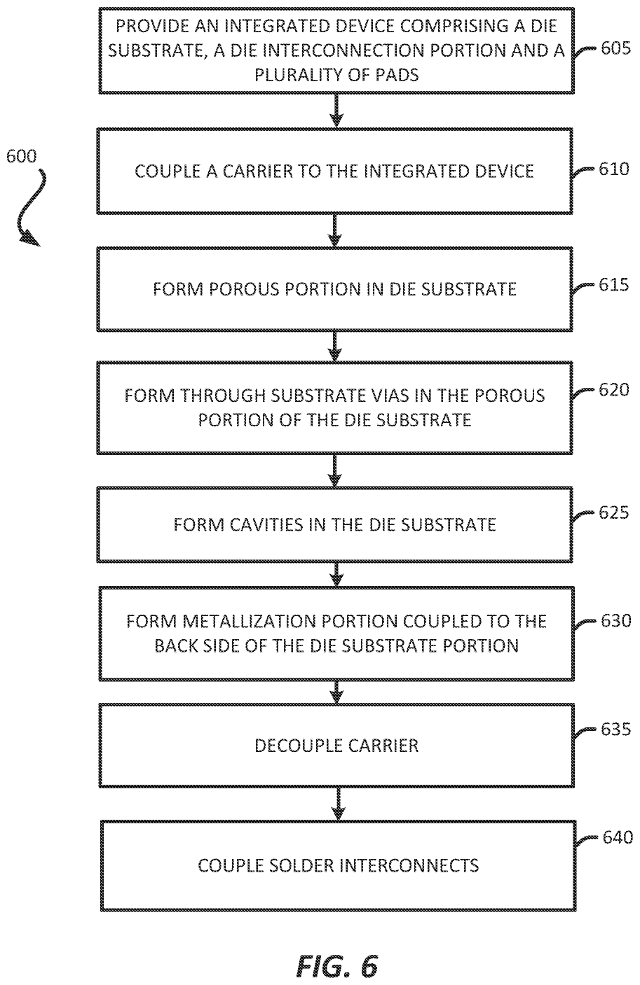

In some implementations, fabricating an integrated device includes several processes. FIG. 6 illustrates an exemplary flow diagram of a method 600 for providing or fabricating an integrated device. In some implementations, the method 600 of FIG. 6 may be used to provide or fabricate the integrated device 200 of FIG. 2 described in the disclosure. However, the method 600 may be used to provide or fabricate any of the integrated devices described in the disclosure.

It should be noted that the method of FIG. 6 may combine one or more processes in order to simplify and/or clarify the method for providing or fabricating an integrated device. In some implementations, the order of the processes may be changed or modified.

The method provides (at 605) an integrated device that includes a die substrate, a die interconnection portion and a plurality of pads. Stage 1 of FIG. 5A, illustrates and describes a state after an integrated device is provided and/or fabricated. The integrated device 200 may include a die substrate portion 102 and a die interconnection portion 104. The die substrate portion 102 includes a die substrate 120 and an active region 108. The die interconnection portion 104 includes at least one dielectric layer 140, a plurality of die interconnects 142, a plurality of pad interconnects 107 and a passivation layer 105. In some implementations, a front side of the integrated device 200 may include the side that includes the passivation layer 105 and/or the plurality of pad interconnects 107. In some implementations, a back side of the integrated device 200 may include the side that includes the die substrate 120.

The method couples (at 610) the integrated device to a carrier. Stage 2 of FIG. 5A, illustrates and describes an example of a state after the integrated device 200 is coupled to a carrier 500. The carrier 500 may be a tape. The carrier may include an adhesive. The front side of the integrated device 200 may be coupled to and touching the carrier 500. For example the passivation layer 105 and/or the plurality of pad interconnects 107 may be coupled to and touch the carrier 500.

The method forms (at 615) a porous portion in the die substrate. Stage 3 of FIG. 5B, illustrates and describes an example of a state after a porous portion 122 is formed in the die substrate 120. It is noted that more than one porous portion may be formed. The porous portion 122 may have a lower density than other portions of the die substrate 120. The die substrate 120 may include silicon. In some implementations, more than one porous portion may be formed in the die substrate 120. In some implementations, the porous portion may have different thicknesses.

A porosification process may be used to form and/or define porous portions in the die substrate 120. A porosification process may include dipping a silicon wafer in an electrolyte of 1:1 mixture of HF and ethanol. A current is then passed, using a platinum rod as cathode while the silicon wafer acts as anode. The substrate is then annealed at 300-400° C. to strengthen the microstructure. An HF-resistant etch-stop layer (e.g., silicon nitride) is used for selective (masked) porosification. However, different implementations may use a porosification process that includes other steps and/or materials.

Different porous portions may have the same porosity or different porosity. As a result of the porosification process, the porous portion may have different coefficients of thermal expansions (e.g., different from other porous portions, different from unporosified portions of the die substrate 120). The porosification process may change the density of the porous portion. In some implementations, one or more porous portions (e.g., 122) may have a porosity in a range of about 30%-70%.

The method forms (at 620) a plurality of through substrate vias in the die substrate, including a plurality of through substrate vias through a porous portion of the die substrate 120. Forming a plurality of through substrate vias may include forming a plurality of via cavities in the die substrate 120.

Stage 4 of FIG. 5B, illustrates and describes an example of a state after a plurality of via cavities 523 are formed in the die substrate 120. The plurality of via cavities 523 may include a first plurality of via cavities 523a and a second plurality of via cavities 523b. The first plurality of via cavities 523a may be formed through the porous portion 122 of the die substrate 120. The second plurality of via cavities 523b may be formed through the bulk portion of the die substrate 120 (e.g., unporosified portion of the die substrate 120). A laser process (e.g., laser ablation) may be used to form the plurality of via cavities 523. In some implementations, the plurality of via cavities 523 may extend into the die interconnection portion 104.

Stage 5 of FIG. 5C, illustrates and describes an example of a state after a plurality of through substrate vias 123 are formed. A plating process may be used to form the plurality of substrate vias 123. The plurality of through substrate vias 123 may include a first plurality of through substrate vias 123a and a second plurality of through substrate vias 123b. The first plurality of through substrate vias 123a may be formed in the first plurality of via cavities 523a. The first plurality of through substrate vias 123a may extend through the porous portion 122 of the die substrate 120. The second plurality of through substrate vias 123b may be formed in the second plurality of via cavities 523b. The second plurality of through substrate vias 123b may extend through an unporosified portion of the die substrate 120. In some implementations, the plurality of through substrate vias 123 may extend into the die interconnection portion 104. The plurality of through substrate vias 123 may be coupled to the plurality of die interconnects 142.

The method optionally forms (at 625) a plurality of cavities in the die substrate. Stage 6 of FIG. 5C, illustrates and describes an example of a state after a plurality of cavities 223 are formed in the die substrate 120. A laser process (e.g., laser ablation) may be used to form the plurality of cavities 223. The plurality of cavities 223 may have the same depth or different depths. The plurality of cavities 223 may extend through the porous portion 122 and/or the unporosified portion of the die substrate 120.

The method forms (at 630) a metallization portion (e.g., 103) that is coupled to the back side of the die substrate portion (e.g., 102). Forming the metallization portion may include forming at least one dielectric layer and a plurality of metallization interconnects. Stage 7 of FIG. 5D, illustrates and describes an example of a state after a plurality of metallization interconnects 532 are formed on the back side surface of the die substrate 120. A plating process may be used to form the plurality of metallization interconnects 532. The plurality of metallization interconnects 532 may be coupled to the plurality of through substrate vias 123.

Stage 8 of FIG. 5D, illustrates and describes an example of a state after a dielectric layer 130 is formed and coupled to the back side surface of the die substrate 120. The dielectric layer 130 may include a plurality of cavities 541. The dielectric layer 130 and the plurality of cavities 541 may be formed and/or provided using a deposition process, a lamination process, an exposure process and/or a development process.

Stage 9 of FIG. 5E, illustrates and describes an example of a state after a plurality of metallization interconnects 542 are formed. The plurality of metallization interconnects 542 may be coupled to the plurality of metallization interconnects 532. A plating process may be used to form the plurality of metallization interconnects 534. The plurality of metallization interconnects 532 and/or the plurality of metallization interconnects 542 may be represented as the plurality of metallization interconnects 132.

The method decouples (at 635) the carrier from the integrated device. Stage 10 of FIG. 5E, illustrates and describes an example of a state after the carrier 500 is decoupled from the integrated device 200. The carrier 500 may be detached and/or peeled off from the integrated device 200.

The method couples (at 640) a plurality of solder interconnects to the integrated device. Stage 11 of FIG. 5F, illustrates and describes an example of a state after the plurality of solder interconnects 106 are coupled to the plurality of pad interconnects 107. A solder reflow process may be used to form and couple the plurality of solder interconnects 106 to the plurality of pad interconnects 107.

### Exemplary Package Comprising an Integrated Device That Includes a Die Substrate with a Porous Portion

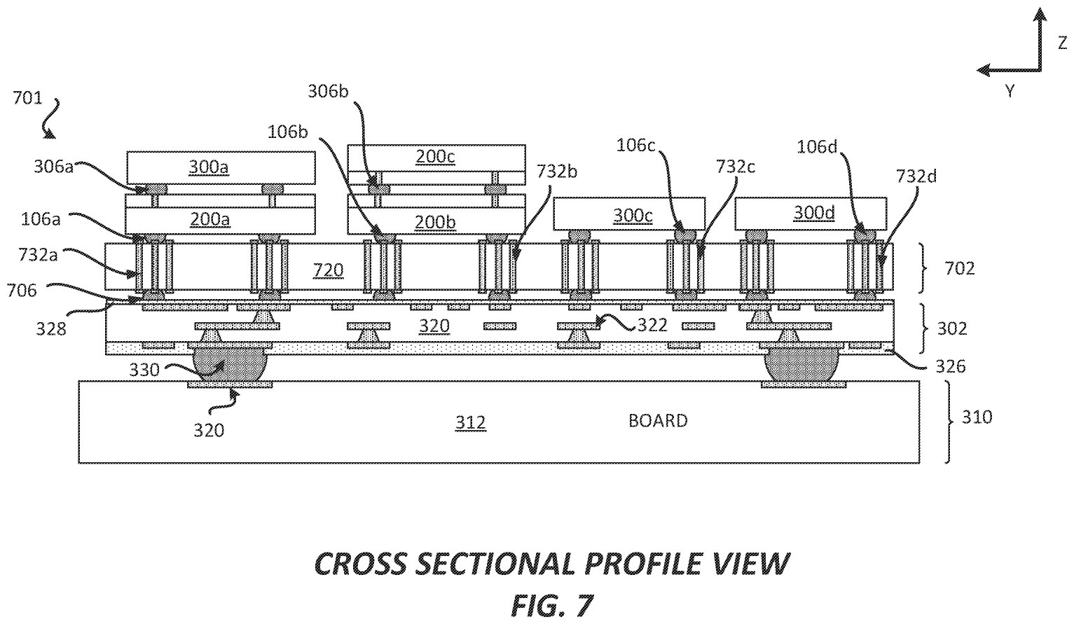

FIG. 7 illustrates a cross sectional profile view of a package 701 that includes an integrated device comprising a die substrate with a porous portion. The package 701 includes the substrate 302, the interposer 702, an integrated device 200a, an integrated device 200b, an integrated device 200c, an integrated device 300a, an integrated device 300b, an integrated device 300c and an integrated device 300d.

The substrate 302 may be a package substrate. The substrate 302 is coupled to the board 310 through a plurality of solder interconnects 330. The interposer 702 is coupled to the substrate 302 through a plurality of solder interconnects 706. The interposer 702 includes a silicon substrate 720 and a plurality of interconnects 732. The plurality of interconnects 732 may include a plurality of interposer interconnects. The plurality of interconnects 732 may include a plurality of via interconnects. The plurality of interconnects 732 may include a plurality of interconnects 732a, a plurality of interconnects 732b, a plurality of interconnects 732c, and a plurality of interconnects 732d .

The integrated device 200a is coupled to the interposer 702 through a plurality of solder interconnects 106a. The integrated device 200b is coupled to the interposer 702 through a plurality of solder interconnects 106b. The integrated device 300c is coupled to the interposer 702 through a plurality of solder interconnects 106c. The integrated device 300d is coupled to the interposer 702 through a plurality of solder interconnects 106d.

The integrated device 300a is coupled to the integrated device 200a through a plurality of solder interconnects 306a. For example, the front side of the integrated device 300a is coupled to the back side of the integrated device 200a through a plurality of solder interconnects 306a, in a similar manner as described in FIGS. 3 and 4. The integrated device 200c is coupled to the integrated device 200b through a plurality of solder interconnects 306b. For example, the back side of the integrated device 200c is coupled to the back side of the integrated device 200b through a plurality of solder interconnects 306b. In such instances, the plurality of solder interconnects 306b may be coupled to the metallization interconnects of the integrated device 200b and the metallization interconnects of the integrated device 200c.

An electrical path to and/or from the integrated device 200a may include at least one solder interconnect from the plurality of solder interconnects 106a, and an interconnect from the plurality of interconnects 732a. An electrical path to and/or from the integrated device 200b may include at least one solder interconnect from the plurality of solder interconnects 106b, and an interconnect from the plurality of interconnects 732b.

An electrical path to and/or from the integrated device 300c may include at least one solder interconnect from the plurality of solder interconnects 106c, and an interconnect from the plurality of interconnects 732c. An electrical path to and/or from the integrated device 300d may include at least one solder interconnect from the plurality of solder interconnects 106d, and an interconnect from the plurality of interconnects 732d.

### Exemplary Sequence for Fabricating an Interposer

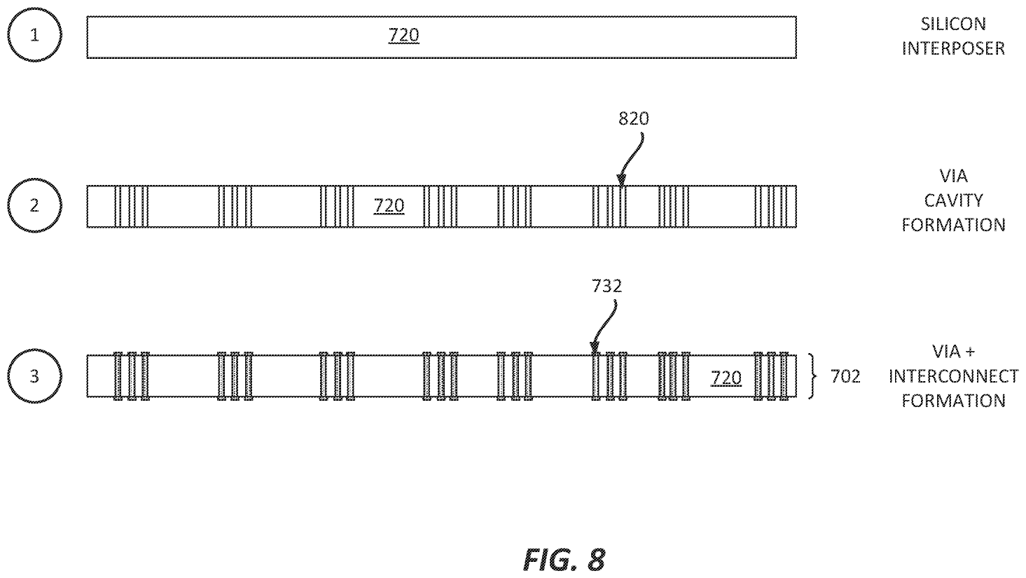

In some implementations, fabricating an integrated device includes several processes. FIG. 8 illustrates an exemplary sequence for providing or fabricating an interposer. In some implementations, the sequence of FIG. 8 may be used to provide or fabricate the interposer 702. However, the process of FIG. 8 may be used to fabricate any of the interposer described in the disclosure.

It should be noted that the sequence of FIG. 8 may combine one or more stages in order to simplify and/or clarify the sequence for providing or fabricating an interposer. In some implementations, the order of the processes may be changed or modified. In some implementations, one or more of processes may be replaced or substituted without departing from the scope of the disclosure.

Stage 1, as shown in FIG. 8, illustrates a state a silicon substrate 720 is provided. The silicon substrate may be silicon block and/or silicon wafer.

Stage 2 illustrates a state after a plurality of via cavities 820 are formed in the silicon substrate 720. A laser ablation process may be used to form the plurality of via cavities 820.

Stage 3 illustrates a state after a plurality of interconnects 732 are formed in the plurality of cavities 820 and on surfaces of the silicon substrate 720. A plating process may be used to form the plurality of interconnects 732. Stage 3 may illustrate an interposer 702 that includes a silicon substrate 720 and a plurality of interconnects 732. The plurality of interconnects 732 may include via interconnects, pad interconnects and/or trace interconnects.

### Exemplary Sequence for Fabricating a Package Comprising an Integrated Device Including a Die Substrate With a Porous Portion

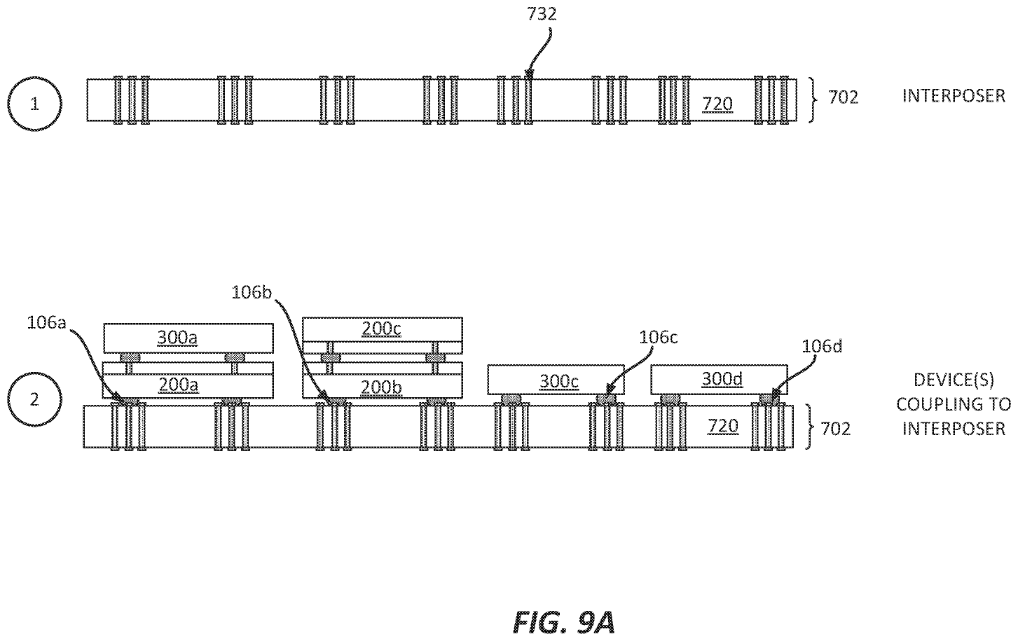

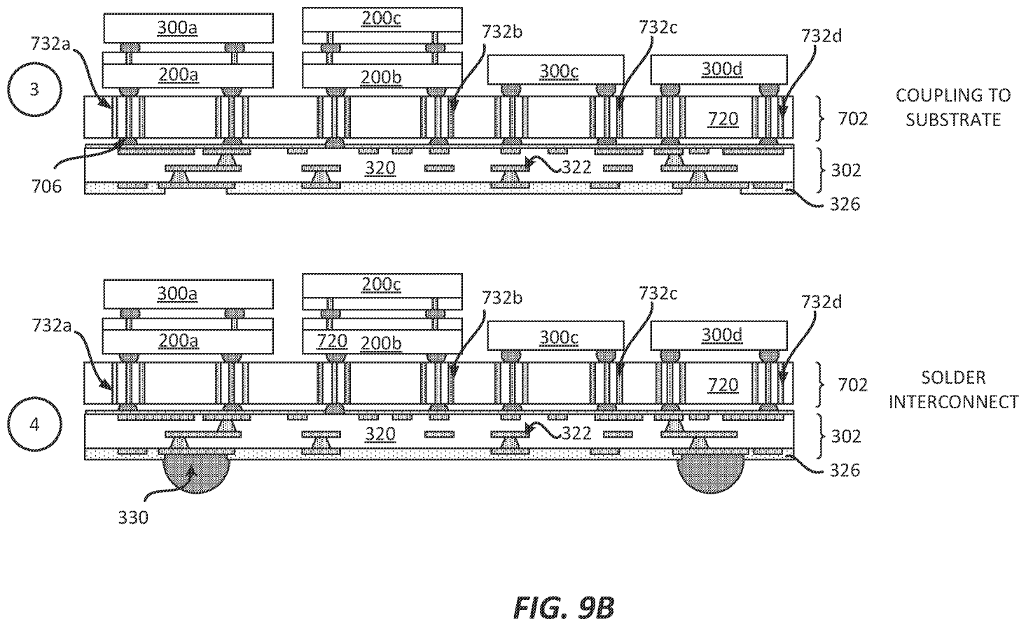

In some implementations, fabricating a package includes several processes. FIGS. 9A-9B illustrate an exemplary sequence for providing or fabricating a package that includes an integrated device comprising a die substrate with a porous portion and a cavity. In some implementations, the sequence of FIGS. 9A-9B may be used to provide or fabricate the package 701. However, the process of FIGS. 9A-9B may be used to fabricate any of the packages described in the disclosure.

It should be noted that the sequence of FIGS. 9A-9B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 9A, illustrates a state after an interposer 702 is provided. The interposer 702 may include a silicon substrate 720 and a plurality of interconnects 732.

Stage 2 illustrates a state after a plurality of integrated devices are coupled to the interposer 702. A plurality of solder interconnects (e.g., 106a, 106b, 106c, 106d) may be used to couple the integrated devices (e.g., 200a, 200b, 300c, 300d) to the plurality of interconnects 732 of the interposer 702. A solder reflow process may be used to form and couple the integrated devices to the plurality of interconnects 732 of the interposer 702.

Stage 3, as shown in FIG. 9B, illustrates a state after the interposer 702 is coupled to the substrate 302 through a plurality of solder interconnects 706. A solder reflow process may be used to form and couple the plurality of solder interconnects 706 to (i) the plurality of substrate interconnects 322 of the substrate 302 and (ii) the plurality of interconnects 732 of the interposer 702.

Stage 4 illustrates a state after a plurality of solder interconnects 330 are coupled to the substrate 302. A solder reflow process may be used to couple the plurality of solder interconnects 330 are coupled to the plurality of substrate interconnects 322 of the substrate 302.

### Exemplary Electronic Devices

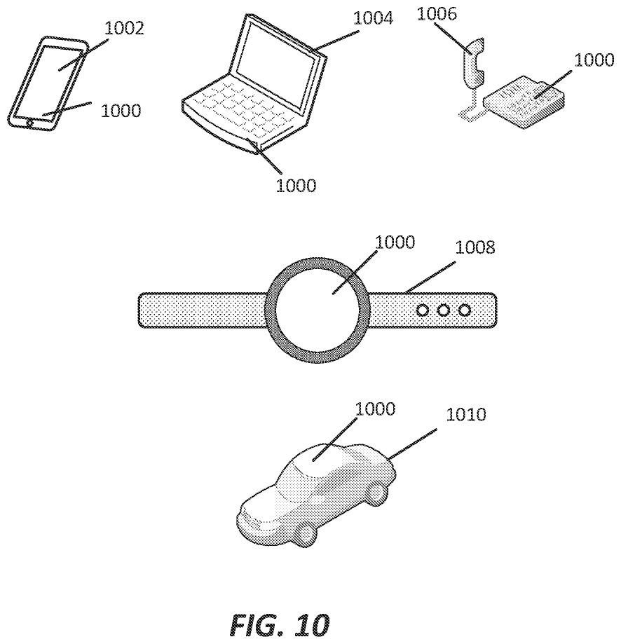

FIG. 10 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5F, 6-8, 9A-9B and/or 10 may be rearranged and/or combined into a single component, process, feature or function or embodied in several components, processes, or functions. Additional elements, components, processes, and/or functions may also be added without departing from the disclosure. It should also be noted FIGS. 1-4, 5A-5F, 6-8, 9A-9B and/or 10 and its corresponding description in the present disclosure is not limited to dies and/or ICs. In some implementations, FIGS. 1-4, 5A-5F, 6-8, 9A-9B and/or 10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object that is coupled to another object may be coupled to at least part of the another object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: An integrated device comprising a die substrate comprising a porous portion; a plurality of through substrate vias extending through the porous portion of the die substrate; and a die interconnection portion coupled to the die substrate.

Aspect 2: The integrated device of aspect 1, wherein the die substrate includes silicon.

Aspect 3: The integrated device of aspects 1 through 2, wherein the die substrate includes an unporosified portion, and wherein the porous portion of the die substrate includes a lower density than the unporosified portion of the die substrate.

Aspect 4: The integrated device of aspects 1 through 3, wherein the porous portion includes a coefficient of thermal expansion (CTE) in a range of about 5-8 parts per million per Celsius degree (ppm/C).

Aspect 5: The integrated device of aspects 1 through 4, wherein the porous portion comprises a first porous portion comprising a first density; and a second porous portion comprising a second density.

Aspect 6: The integrated device of aspect 5, wherein the first porous portion comprises a first coefficient of thermal expansion (CTE), and wherein the second porous portion comprises a second coefficient of thermal expansion (CTE).

Aspect 7: The integrated device of aspect 6, wherein the die substrate includes an unporosified portion comprising a third coefficient of thermal expansion (CTE) that is different from the first coefficient of thermal expansion (CTE) and the second coefficient of thermal expansion (CTE).

Aspect 8: The integrated device of aspects 1 through 7, wherein the porous portion comprises a porosity in a range of about 30-70 percent.

Aspect 9: The integrated device of aspects 1 through 8, further comprising a metallization portion coupled to a back side of the die substrate.

Aspect 10: The integrated device of aspect 9, wherein the metallization portion comprises at least one dielectric layer; and a plurality of metallization interconnects coupled to the plurality of through substrate vias.

Aspect 11: The integrated device of aspect 10, wherein the plurality of metallization interconnects include a plurality of redistribution interconnects.

Aspect 12: The integrated device of aspects 1 through 11, further comprising at least one cavity in the die substrate.

Aspect 13: The integrated device of aspects 1 through 12, wherein a total surface area of all of the plurality of through substrate vias is at least 2 percent of a total surface area of the die substrate.

Aspect 14: The integrated device of aspects 1 through 13, further comprising an active region.

Aspect 15: The integrated device of aspect 14, wherein the active region includes a plurality of logic cells, a plurality of transistors, and/or a plurality of filters.

Aspect 16: The integrated device of claim 1, wherein the integrated device is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 17: A package comprising an interposer; and a first integrated device coupled to the interposer through at least a plurality of solder interconnects. The first integrated device comprises a die substrate comprising a porous portion; a plurality of through substrate vias extending through the porous portion of the die substrate; and a die interconnection portion coupled to the die substrate.

Aspect 18: The package of aspect 17, wherein the die substrate includes silicon.

Aspect 19: The package of aspects 17 through 18, wherein the die substrate includes an unporosified portion, and wherein the porous portion of the die substrate includes a lower density than the unporosified portion of the die substrate.

Aspect 20: The package of aspects 17 through 19, wherein the porous portion comprises a first porous portion comprising a first coefficient of thermal expansion (CTE), and a second porous portion comprising a second coefficient of thermal expansion (CTE), wherein the die substrate includes an unporosified portion comprising a third coefficient of thermal expansion (CTE) that is different from the first coefficient of thermal expansion (CTE) and the second coefficient of thermal expansion (CTE).

Aspect 21: The package of aspects 17 through 20, wherein the first integrated device further comprises a metallization portion coupled to a back side of the die substrate.

Aspect 22: The package of aspect 21, wherein the metallization portion comprises at least one dielectric layer; and a plurality of metallization interconnects coupled to the plurality of through substrate vias.

Aspect 23: The package of aspects 21 through 22, further comprising a second integrated device coupled to the metallization portion of the first integrated device through a second plurality of solder interconnects.

Aspect 24: The package of aspects 17 through 22, further comprising a second integrated device coupled to the interposer through a second plurality of solder interconnects.

Aspect 25: The package of aspects 17 through 24, further comprising at least one cavity in the die substrate.

Aspect 26: The package of aspects 17 through 25, wherein the interposer includes a silicon substrate and a plurality of interposer interconnects.

Aspect 27: The package of aspect 26, further comprising a substrate coupled to the interposer through a second plurality of solder interconnects.

Aspect 28: A package comprising a substrate; and a first integrated device coupled to the substrate through at least a plurality of solder interconnects. The first integrated device comprises a die substrate comprising a porous portion; a plurality of through substrate vias extending through the porous portion of the die substrate; and a die interconnection portion coupled to the die substrate.

Aspect 29: The package of aspect 28, wherein the die substrate includes silicon.

Aspect 30: The package of aspects 28 through 29, wherein the die substrate includes an unporosified portion, and wherein the porous portion of the die substrate includes a lower density than the unporosified portion of the die substrate.

Aspect 31: The package of aspects 28 through 30, wherein the porous portion comprises a first porous portion comprising a first coefficient of thermal expansion (CTE), and a second porous portion comprising a second coefficient of thermal expansion (CTE), wherein the die substrate includes an unporosified portion comprising a third coefficient of thermal expansion (CTE) that is different from the first coefficient of thermal expansion (CTE) and the second coefficient of thermal expansion (CTE).

Aspect 32: The package of aspects 28 through 31, further comprising a second integrated device coupled to the first integrated device through a second plurality of solder interconnects.

Aspect 33: The package of aspects 28 through 31, further comprising a second integrated device coupled to the substrate through a second plurality of solder interconnects.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die substrate comprising a porous portion;
a plurality of through substrate vias extending through the porous portion of the die substrate; and
a die interconnection portion coupled to the die substrate.

2. The integrated device of claim 1, wherein the die substrate includes silicon.

3. The integrated device of claim 2,
wherein the die substrate includes an unporosified portion, and
wherein the porous portion of the die substrate includes a lower density than the unporosified portion of the die substrate.

4. The integrated device of claim 1, wherein the porous portion includes a coefficient of thermal expansion (CTE) in a range of about 5-8 parts per million per Celsius degree (ppm/C).

5. The integrated device of claim 1, wherein the porous portion comprises:
a first porous portion comprising a first density; and
a second porous portion comprising a second density.

6. The integrated device of claim 5,
wherein the first porous portion comprises a first coefficient of thermal expansion (CTE), and
wherein the second porous portion comprises a second coefficient of thermal expansion (CTE).

7. The integrated device of claim 6, wherein the die substrate includes an unporosified portion comprising a third coefficient of thermal expansion (CTE) that is different from the first coefficient of thermal expansion (CTE) and the second coefficient of thermal expansion (CTE).

8. The integrated device of claim 1, wherein the porous portion comprises a porosity in a range of about 30-70 percent.

9. The integrated device of claim 1, further comprising a metallization portion coupled to a back side of the die substrate.

10. The integrated device of claim 9, wherein the metallization portion comprises:
at least one dielectric layer; and
a plurality of metallization interconnects coupled to the plurality of through substrate vias.

11. The integrated device of claim 10, wherein the plurality of metallization interconnects include a plurality of redistribution interconnects.

12. The integrated device of claim 1, further comprising at least one cavity in the die substrate.

13. The integrated device of claim 1, wherein a total surface area of all of the plurality of through substrate vias is at least 2 percent of a total surface area of the die substrate.

14. The integrated device of claim 1, further comprising an active region.

15. The integrated device of claim 14, wherein the active region includes a plurality of logic cells, a plurality of transistors, and/or a plurality of filters.

16. The integrated device of claim 1, wherein the integrated device is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

17. A package comprising:
an interposer; and
a first integrated device coupled to the interposer through at least a plurality of solder interconnects, wherein the first integrated device comprises:
a die substrate comprising a porous portion;
a plurality of through substrate vias extending through the porous portion of the die substrate; and
a die interconnection portion coupled to the die substrate.

18. The package of claim 17, wherein the die substrate includes silicon.

19. The package of claim 18,
wherein the die substrate includes an unporosified portion, and
wherein the porous portion of the die substrate includes a lower density than the unporosified portion of the die substrate.

20. The package of claim 17, wherein the porous portion comprises:
a first porous portion comprising a first coefficient of thermal expansion (CTE), and
a second porous portion comprising a second coefficient of thermal expansion (CTE),
wherein the die substrate includes an unporosified portion comprising a third coefficient of thermal expansion (CTE) that is different from the first coefficient of thermal expansion (CTE) and the second coefficient of thermal expansion (CTE).

21. The package of claim 17, wherein the first integrated device further comprises a metallization portion coupled to a back side of the die substrate.

22. The package of claim 21, wherein the metallization portion comprises:
at least one dielectric layer; and
a plurality of metallization interconnects coupled to the plurality of through substrate vias.

23. The package of claim 21, further comprising a second integrated device coupled to the metallization portion of the first integrated device through a second plurality of solder interconnects.

24. The package of claim 17, further comprising a second integrated device coupled to the interposer through a second plurality of solder interconnects.

25. The package of claim 17, further comprising at least one cavity in the die substrate.

26. The package of claim 17, wherein the interposer includes a silicon substrate and a plurality of interposer interconnects.

27. The package of claim 26, further comprising a substrate coupled to the interposer through a second plurality of solder interconnects.

28. A package comprising:
a substrate; and
a first integrated device coupled to the substrate through at least a plurality of solder interconnects, wherein the first integrated device comprises:
a die substrate comprising a porous portion;
a plurality of through substrate vias extending through the porous portion of the die substrate; and
a die interconnection portion coupled to the die substrate.

29. The package of claim 28, wherein the die substrate includes silicon.

30. The package of claim 29,
wherein the die substrate includes an unporosified portion, and
wherein the porous portion of the die substrate includes a lower density than the unporosified portion of the die substrate.

31. The package of claim 28, wherein the porous portion comprises:
a first porous portion comprising a first coefficient of thermal expansion (CTE), and
a second porous portion comprising a second coefficient of thermal expansion (CTE),
wherein the die substrate includes an unporosified portion comprising a third coefficient of thermal expansion (CTE) that is different from the first coefficient of thermal expansion (CTE) and the second coefficient of thermal expansion (CTE).

32. The package of claim 28, further comprising a second integrated device coupled to the first integrated device through a second plurality of solder interconnects.

33. The package of claim 28, further comprising a second integrated device coupled to the substrate through a second plurality of solder interconnects.
